(19) United States
(12) Patent Application Publication
(10) Pub. No.: US 2025/0248050 A1
(43) Pub. Date: Jul. 31, 2025

(54) NON-VOLATILE MEMORY CELL BASED ON THRESHOLD SWITCH AND OPERATION METHOD THEREOF

(71) Applicant: HUAZHONG UNIVERSITY OF SCIENCE AND TECHNOLOGY, Hubei (CN)

(72) Inventors: Hao TONG, Hubei (CN); Jinyu WEN, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 18/272,593

(22) PCT Filed: Oct. 4, 2022
(86) PCT No.: PCT/CN2022/123694

§ 371 Date: Apr. 1, 2025

(30) Foreign Application Priority Data
Jun. 22, 2022 (CN) 202210713336.7

(51) Int. Cl. H10B 63/00; G11C 13/00

(52) U.S. Cl. CPC H10B 63/24; G11C 13/004; G11C 13/0069

(57) ABSTRACT

The invention discloses a non-volatile memory cell based on a threshold switch and an operation method thereof, which belong to micro-nano electronics technology. The non-volatile memory cell includes a first metal electrode layer, a threshold switch layer, and a second metal electrode layer stacked in sequence. The threshold switch layer contains a chalcogenide semiconductor material, and the threshold voltage of the threshold switch layer is able to be switched between initial threshold voltage and high threshold voltage under the operation of an electric signal. The non-volatile memory cell realizes storage of information based on the threshold change controllable by the threshold switch. The advantages of such threshold switch lie in nanosecond-level switching speed, good scalability and easy three-dimensional stacking. The realized novel threshold switch memory cell also has the above-mentioned advantages, and is expected to be applied in DRAM application scenarios where the technology node is less than 20 nm. The storage density may be improved considerably on the premise of matching the access speed of DRAM. Moreover, the non-volatile memory cell based on the threshold switch has a low process cost and is compatible with the CMOS process, which facilitates the large-scale production of the memory cell.

### BACKGROUND

### Technical Field

The disclosure relates to micro-nano electronics technology, in particular to a non-volatile memory cell based on a threshold switch and an operation method thereof.

### Description of Related Art

Dynamic Random Access Memory (DRAM) has been used as the main memory of computer storage architecture for the past few decades because of speed and storage density as its advantages. However, as the technology node has now arrived at 20 nm, DRAM is limited by the reduction in capacitance and the increase in transistor leakage caused by size reduction, which is very close to the physical limit of size reduction. Moreover, the complex process and high cost required for further reduction of DRAM further cause gradual saturation of the cost benefits brought by its miniaturization, which causes barriers in terms of physical size and cost and results in a “miniature wall”.

In light of the above, it is necessary to develop a new type of memory with a smaller processing size on the premise of matching the access speed of the DRAM. Currently, among several mainstream new memories based on the resistance transition mechanism, the interior of memory cells of resistive random access memory (RRAM) and phase-change memory (PCM) have to undergo structural non-volatile transition in the resetting and setting processes, their reading and setting speed can hardly match DRAM. Meanwhile, although spin-transfer torque magnetoresistance Random Access Memory (STT-MRAM) based on spin-transfer torque has favorable reading and setting speeds, such memory is inferior in terms of scalability, storage density and cost, and is considered to be more suitable for application scenarios of static random-access memory (SRAM). In the meantime, significant size reduction problem is also challenging for Ferroelectric RAM (FeRAM).

### SUMMARY

In order to make scalability and transition speed to sufficiently match DRAM, an embodiment of the present disclosure provides a non-volatile memory cell based on a threshold switch. The technical scheme is as follows.

The non-volatile memory cell includes a first metal electrode layer, a threshold switch layer, and a second metal electrode layer stacked in sequence. The threshold switch layer contains a chalcogenide semiconductor material, and the threshold voltage of the threshold switch layer is able to be switched between initial threshold voltage and high threshold voltage under the operation of an electric signal.

Further, the threshold switch layer is a single-layer structure.

Further, the threshold switch layer is a multi-layer structure, the threshold switch layer is an asymmetric multi-layer structure, and the threshold switch layer includes m first sub-layers and m second sub-layers stacked alternately and periodically, where m≥1, and the chalcogenide semiconductor material of the first sublayer is different from the chalcogenide semiconductor material of the second sublayer.

Further, the threshold switch layer is a multi-layer structure, the constituent elements of the chalcogenide semiconductor material in the first sublayer and the chalcogenide semiconductor material in the second sublayer are different. Alternatively, the chalcogenide semiconductor material of the first sublayer and the chalcogenide semiconductor material of the second sublayer have the same constituent elements, and the atomic percentages of various elements are different.

Further, the chalcogenide semiconductor material is selected from at least one of SiTex, CTex, BTex, GeTex, AlTex, GeSbx, BiTex, AsTex, SnTex, MgTex, GeSex, SbSex, BiSex, AsSex, GeSx, and GaSx. Alternatively, the chalcogenide semiconductor material is selected from at least one of doped SiTex, CTex, BTex, GeTex, AlTex, GeSbx, BiTex, AsTex, SnTex, MgTex, GeSex, SbSex, BiSex, AsSex, GeSx, and GaSx, and the doping element is selected from at least one of N, Sb, Si, and C.

On the other hand, an embodiment of the present disclosure further provides an operation method of a non-volatile memory cell based on a threshold switch, and the operation method includes a reset operation, which is specifically as follows.

When the threshold voltage of the threshold switch layer is at the initial threshold voltage, a first scan operation is performed on the non-volatile memory cell, so that the threshold voltage of the threshold switch layer is switched from the initial threshold voltage to a high threshold voltage. The first scan operation and the second scan operation have opposite electrical properties, the voltage amplitude of the first scan operation is higher than the initial threshold voltage, and the second scan operation is an initial operation for obtaining an initial threshold voltage of the threshold switch layer.

Further, the operation method also includes a set operation, and is specifically as follows.

When the threshold voltage of the threshold switch layer is at the high threshold voltage, a third scan operation is performed on the non-volatile memory cell, so that the threshold voltage of the threshold switch layer is switched from the high threshold voltage to the initial threshold voltage. The amplitude of the third scan operation is higher than the high threshold voltage, and the third scan operation has the same electrical properties as the second scan operation.

Further, the operation method also includes a read operation, and is specifically as follows.

A fourth scan operation is performed on the non-volatile memory cell, and the voltage of the fourth scan operation is between an initial threshold voltage and a high threshold voltage.

Further, the first scan operation is DC scanning or pulse scanning, the waveform of the pulse scanning includes square wave, triangular wave and trapezoidal wave. The absolute value of the DC scanning range or the absolute value of the pulse scanning amplitude of the first scan operation is greater than the initial threshold voltage, and the pulse width of the pulse scanning is greater than the minimum value for turning on the non-volatile memory cell.

Further, the third scan operation is DC scanning or pulse scanning, and the waveform of the pulse scanning includes square wave, triangular wave and trapezoidal wave. The absolute value of the DC scanning range or the absolute value of the pulse scanning amplitude of the third scan operation is greater than the high threshold voltage, and the pulse width of the pulse scanning is greater than the minimum value for turning on the non-volatile memory cell.

The advantageous effects brought by the technical solutions provided by the embodiments of the present disclosure at least include the following.

The disclosure provides a non-volatile memory cell based on a threshold switch, which realizes storage of information based on the threshold change controllable by the threshold switch. The advantages of such threshold switch lie in nanosecond-level switching speed, good scalability and easy three-dimensional stacking. The realized novel threshold switch memory cell also has the above-mentioned advantages, and is expected to be applied in DRAM application scenarios where the technology node is less than 20 nm. In that case, the storage density may be improved considerably on the premise of matching the access speed of DRAM. Moreover, the non-volatile memory cell based on the threshold switch has a low process cost and is compatible with the CMOS process, which facilitates the large-scale production of the memory cell.

### BRIEF DESCRIPTION OF THE DRAWINGS

In order to more clearly illustrate the technical solutions of the embodiments of the present disclosure, the following briefly introduces the drawings that need to be used in the description of the embodiments. Clearly, the drawings in the following description are some embodiments of the present disclosure. Those of ordinary skill in the art can also obtain other drawings based on these drawings on the premise of not making creative efforts.

FIG. 1 is a structural schematic view of a non-volatile memory cell of the present disclosure.

FIG. 2 is a structural schematic view of another non-volatile memory cell of the present disclosure.

FIG. 3 is a structural schematic view of still another non-volatile memory cell of the present disclosure.

FIG. 4 is a schematic view illustrating a non-volatile memory cell of the present disclosure realizing reset operation and set operation.

FIG. 5 is a voltage-current curve diagram of a reset operation and a set operation of a non-volatile memory cell in Embodiment 1 of the present disclosure.

FIG. 6 is a voltage-current curve diagram of a reset operation and a set operation of a non-volatile memory cell in Embodiment 2 of the present disclosure.

### DESCRIPTION OF THE EMBODIMENTS

In order to make the object, technical solution and advantages of the present disclosure clearer, the present disclosure will be further described in detail below in conjunction with the accompanying drawings and embodiments. It should be understood that the specific embodiments described here are only used to explain the present disclosure, not to limit the present disclosure. In addition, the technical features involved in the various embodiments of the present disclosure described below can be combined with each other as long as they do not constitute a conflict with each other.

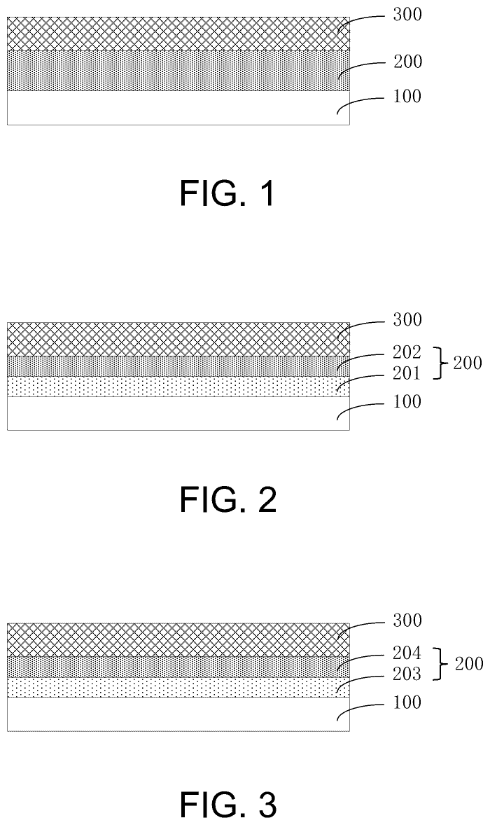

An embodiment of the present disclosure provides a non-volatile memory cell based on a threshold switch. FIG. 1 is a structural schematic view of a non-volatile memory cell based on a threshold switch in an embodiment of the present disclosure. As shown in FIG. 1, the non-volatile memory cell includes a first metal electrode layer 100, a threshold switch layer 200, and a second metal electrode layer 300 stacked in sequence. The threshold switch layer 200 contains a chalcogenide semiconductor material, and the threshold voltage of the threshold switch layer 200 may be controlled by an electric signal to switch between an initial threshold voltage Vth and a high threshold voltage Vhigh.

The threshold voltage of the threshold switch layer 200 is defined as in the “1” state when the threshold voltage is the initial threshold voltage Vth, and the threshold voltage of the threshold switch layer 200 is defined as in the “0” state when the threshold voltage is the high threshold voltage Vhigh. By switching between the initial threshold voltage Vth and the high threshold voltage Vhigh to represent the “1” state and “0” state of data, the purpose of storing data is achieved, and storage of information is realized based on the threshold change controllable by the threshold switch. The advantages of the threshold switch lie in nanosecond switching speed, good scalability and easy three-dimensional stacking. The realized novel threshold switch memory cell also has the above-mentioned advantages, and is expected to be applied in DRAM application scenarios where the technology node is less than 20 nm. In that case, the storage density may be improved considerably on the premise of matching the access speed of DRAM. Moreover, the non-volatile memory cell based on the threshold switch has a low process cost and is compatible with the CMOS process, which facilitates the large-scale production of the memory cell.

In some embodiments, the threshold voltage of the threshold switch layer 200 may be switched between the initial threshold voltage Vth and the high threshold voltage Vhigh through reverse scan conduction and forward scan conduction. For the specific implementation method and principle, please refer to the operation method of the non-volatile memory cell described below.

Further, the chalcogenide semiconductor material is selected from at least one of SiTex, CTex, BTex, GeTex, AlTex, GeSbx, BiTex, AsTex, SnTex, MgTex, GeSex, SbSex, BiSex, AsSex, GeSx, and GaSx. Alternatively, the chalcogenide semiconductor material is selected from at least one of doped SiTex, CTex, BTex, GeTex, AlTex, GeSbx, BiTex, AsTex, SnTex, MgTex, GeSex, SbSex, BiSex, AsSex, GeSx, and GaSx, and the doping element is selected from at least one of N. Sb, Si, and C.

In some embodiments, as shown in FIG. 1, the threshold switch layer 200 is a single-layer structure.

In some embodiments, as shown in FIG. 2, the threshold switch layer 200 is a multi-layer structure, and the threshold switch layer includes m first sublayers 201 and m second sublayers 202 that are periodically and alternately stacked, where m≥1th. The constituent elements of the chalcogenide semiconductor material of the first sublayer 201 and the chalcogenide semiconductor material of the second sublayer 202 are different.

In some embodiments, as shown in FIG. 3, the threshold switch layer 200 has a multi-layer structure, and the threshold switch layer includes n third sublayers 203 and n fourth sublayers 204 that are periodically and alternately stacked, where n≥1. The chalcogenide semiconductor material of the third sublayer 203 and the chalcogenide semiconductor material of the fourth sublayer 204 have the same constituent elements, and the atomic percentages of various elements are different.

Asymmetric threshold switch layers with different constituent elements or different element ratios have different delocalization/localization processes when they are turned on/off. For an asymmetric structure (including two categories) with only two layers of chalcogenide semiconductor materials, after the initial threshold voltage has been forward-conducted, the conductive path and localization ratio have only slight changes. After applying a reverse electric field to the device to turn the device on and off, the principle of realizing the threshold voltage increment ΔVth (the difference between the initial threshold voltage Vth and the high threshold voltage Vhigh) within the respective layers is similar to that of a single-layer structure. However, due to the differences in the delocalization/localization process between different layers, when the two layers are considered separately, there is a deviation between the theoretical next forward conductive paths of each layer, that is, there is a local optimal solution for its conduction in a single layer. As a whole, due to the theoretical deviation between the conductive paths of the two layers and the influence of the interface effect between the two layers, the global optimal solution of the conductive path as a whole is different from that of any single layer, that is, the external field required for the global optimal solution is greater than the sum of the external fields required for the two single-layer local optimal solutions. Therefore, the asymmetric multilayer structure has a larger threshold voltage increment than the single layer in the next forward conduction. In the meantime, alternately stacked threshold switch layers are adopted, and the thickness of each layer is much smaller than that of a single threshold switch layer. The thinner thickness helps to generate a greater localization ratio of the device after the action of the negative external field is applied. When the threshold switch layers have the same thickness, alternate stacking also contributes to the increase of the threshold voltage increment ΔVth.

Optionally, both the first electrode layer and the second electrode layer are inert electrode materials, and the inert electrode material is at least one of W, TiW, Pt, Au, Ru, Al, TIN, Ta, TaN, IrO₂, ITO and IZO.

An operation method of a non-volatile memory cell based on a threshold switch, which is applicable to the above non-volatile memory cell. In some embodiments, the operation method includes initial operations, and is specifically as follows.

A second scan operation is applied to the non-volatile memory cell to obtain the initial threshold voltage Vth of the threshold switch layer.

The threshold voltage of the threshold switch layer 200 is defined as the “1” state of the non-volatile memory cell when the threshold voltage is the initial threshold voltage Vth, and the second scan operation is specified as the forward scanning of the non-volatile memory cell.

Optionally, the second scan operation may be DC scanning or pulse scanning.

It may be understood that the initial operation serves to determine the initial threshold voltage Vth, which is only performed once at the very beginning, and does not need to be performed every time data is stored.

In some embodiments, the operation method includes a reset operation, and is specifically as follows.

When the threshold voltage of the threshold switch layer is at the initial threshold voltage Vth, the first scan operation is performed on the non-volatile memory cell, so that the threshold voltage of the threshold switch layer is switched from the initial threshold voltage Vth to the high threshold voltage Vhigh. The voltage amplitude of the first scan operation is higher than the initial threshold voltage, the first scan operation and the second scan operation have opposite electrical properties, and the second scan operation is an initial operation for obtaining the initial threshold voltage Vth of the threshold switch layer.

When the memory cell is in the “1” state, the first scan operation is performed on the non-volatile memory cell, so that the non-volatile memory cell is turned off after the reverse conduction. As a result, the threshold voltage of the non-volatile memory cell generates a threshold voltage increment ΔVth (ΔVth>0) on the basis of the initial threshold voltage Vth during the next forward conduction, and the threshold voltage becomes a high threshold voltage Vhigh (Vth+ΔVth). The threshold voltage of the threshold switch layer 200 is defined as the “0” state of the non-volatile memory cell when the threshold voltage is the high threshold voltage Vhigh state.

The threshold switch mechanism may be explained as the delocalization/localization process of electrons in the defect causes the formation and breakage of the conductive path. Under the action of the same external field, the conductive path of the device has some dependence, and only part of the defect is localized after the external field is lost. When the threshold voltage of the threshold switch layer is at the initial threshold voltage Vth (“1” state), the first scan operation and the second scan operation have opposite electrical properties, and the area for applying a reverse electric field to delocalize the device to form a conductive path in a region is different from the forward direction, and therefore reverse electric field localizes defects that are not localized when part of the forward conducting path are broken. Moreover, there will be a deviation between the conduction path of the next forward conduction and when no reverse electric field is applied, which will cause the conduction of the device under the next forward external field to require a larger electric field, that is, a threshold voltage increment ΔVth will be generated. Accordingly, the threshold voltage of the threshold switch layer is switched from the initial threshold voltage Vth to the high threshold voltage Vhigh, and then the non-volatile memory cell is changed from a “1” state to a “0” state, and the reset operation is completed.

Optionally, the first scan operation is DC scanning or pulse scanning, and pulse scanning waveforms include square waves, triangular waves and trapezoidal waves, and the above waveforms with various amplitudes and rise and fall times are all applicable. The absolute value of the DC scanning range or the pulse scanning amplitude of the first scan operation is greater than the initial threshold voltage, and the pulse width of the pulse scanning is greater than the minimum value for turning on the non-volatile memory cell.

In some embodiments, the operation method also includes a set operation, and is specifically as follows.

When the threshold voltage of the threshold switch layer is at the high threshold voltage Vhigh, a third scan operation is performed on the non-volatile memory cell, so that the threshold voltage of the threshold switch layer is switched from the high threshold voltage to the initial threshold voltage, and the amplitude of the third scan operation is higher than the high threshold voltage. The third scan operation has the same electrical property as the second scan operation.

When the threshold voltage of the threshold switch layer is at the high threshold voltage (“0” state), the amplitude of the third scan operation is higher than the high threshold voltage, making the device to be forward conducting. After forward conduction, the proportion of defects localized after losing the external field is similar to that without applying a reverse electric field, so that the threshold voltage of the threshold switch layer is switched from the high threshold voltage Vhigh to the initial threshold voltage Vth, thereby making the non-volatile memory cell to change from “0” state to “1” state, and the set operation is completed.

Optionally, the third scan operation is DC scanning or pulse scanning, the waveform of pulse scanning includes square wave, triangular wave and trapezoidal wave, and the absolute value of the DC scanning range or the absolute value of the pulse scanning amplitude of the third scan operation is greater than the high threshold voltage. The pulse width of the pulse scanning is greater than the minimum value that makes the non-volatile memory cell turn on.

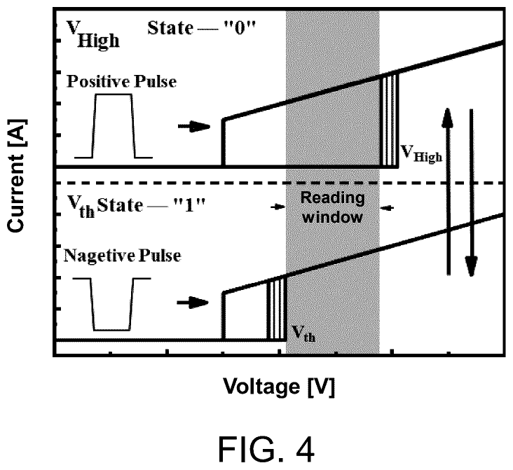

FIG. 4 is a schematic view illustrating a memory cell of the present disclosure realizing reset operation and set operation. As shown in FIG. 4, DC scanning or pulse scanning is applied to the non-volatile memory cell to obtain the initial threshold voltage Vth of the device, and the state is defined as the “1” state of the memory cell. Moreover, it is specified that DC scanning or pulse scanning is forward scanning of memory cell. A reset operation is performed on the memory cell, the first scan operation (reverse scanning) with the polarity opposite to the above-mentioned DC scanning or pulse scanning is applied to the non-volatile memory cell, so that the initial threshold voltage Vth of the device increases by a threshold voltage increment ΔVth (ΔVth>0) after the first scan operation. Vth+ΔVth is defined as the high threshold voltage Vhigh, and the high threshold voltage state Vhigh is defined as the “0” state of the memory cell, then the above operation is the reset (set “0”) operation of the memory cell. When the memory cell is in the “0” state, the third scan operation (forward scanning) with a pulse amplitude higher than Vhigh is adopted to perform an operation on the non-volatile memory cell. After the non-volatile memory cell is turned on, the threshold voltage will spontaneously return to the initial threshold voltage Vth, so that the non-volatile memory cell is in the “1” state, then the above operation is the set (set “1”) operation of the non-volatile memory cell.

In some embodiments, the operation method also includes a read operation, and is specifically as follows.

A fourth scan operation is performed on the non-volatile memory cell, and the voltage of the fourth scan operation is between the initial threshold voltage and the high threshold voltage.

When the non-volatile memory cell is in the “1” state, the reading voltage may turn on the non-volatile memory cell to read low resistance, and since the 1 state is the initial threshold voltage state, repeated reading will not change the threshold voltage thereof, that is, the 1 state may be read repeatedly. When the non-volatile memory cell is in the “0” state, since the reading voltage is lower than the threshold voltage Vhigh at this time, the device cannot be turned on to change the state of the device. Therefore, the reading voltage always reads high resistance, that is, 0 state may be read repeatedly. In summary, the read operation of the non-volatile memory cell is a non-destructive read, that is, the memory cell is non-volatile.

Further, the fourth scan operation is a pulse scanning, and the pulse width is the minimum pulse width that enables the non-volatile memory cell to be turned on when the non-volatile memory cell is in the “1” state.

The present disclosure will be further described below in conjunction with drawings and embodiments.

### Example 1

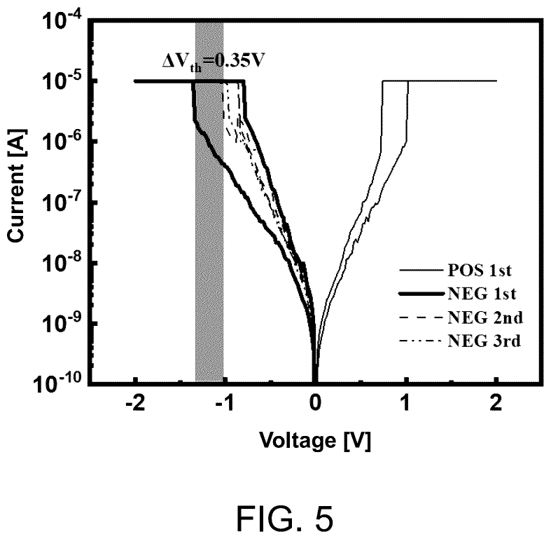

A non-volatile memory cell based on a threshold switch has a structure shown in FIG. 1. the non-volatile memory cell includes a first metal electrode layer 100, a threshold switch layer 200, and a second metal electrode layer 300 stacked in sequence, and the threshold switch layer is a single-layer threshold switch layer GeTex. In order to clearly show the change of the threshold state of the memory cell, in this embodiment, DC voltage scanning is adopted, and the analysis focuses on the set operation and the reading voltage range of the non-volatile memory cell, and the result is shown in FIG. 5. In this embodiment, the negative electrical property of the device are adopted to store information. It is specified that the negative direction of the voltage coordinate in FIG. 5 is the positive operation of the non-volatile memory cell, that is, the electrical direction of the first scan operation is the positive direction of the voltage coordinate, and the electrical direction of the third scan operation is the negative direction of the voltage coordinate.

To implement a reset (reset “0”) operation, a reverse scan (POS 1st in the figure) is applied to the device, which is the first reverse scan operation applied. Then, a third scan operation (NEG 1st in the figure) is applied to the device with a threshold voltage of 1.35V to verify that in this example, the threshold voltage is raised to 1.35V after the second scan operation (POS 1st in the figure).

After undergoing NEG 2nd and NEG 3rd voltage scans, the threshold voltage of the device is about 1.0V, indicating that after the third scan operation (NEG 1st in the figure) turns on the device, and the threshold voltage of the device spontaneously drops to 1.0V, that is, NEG 1st realizes the set (set “1”) operation of the memory cell. In the meantime, the NEG 2nd and NEG 3rd voltage scans confirm that the device will be stable in the “1” state when the device is repeatedly turned on, confirming the non-volatility of the device when the device is repeatedly read.

Since the initial threshold voltage is 1.0V, the high threshold voltage is increased to 1.35V, indicating that the second scan operation (POS 1st) increases the increment ΔVth of the threshold voltage by 0.35V, and the voltage range from 1.0V to 1.35V is the read voltage window of the memory cell.

### Example 2

A non-volatile memory cell based on a threshold switch has a structure as shown in FIG. 3. The non-volatile memory cell includes a first metal electrode layer 100, a threshold switch layer 200, and a second metal electrode layer 300 stacked in sequence. The threshold switch layer 200 is a multi-layer structure, and the threshold switch layer includes n third sublayers 203 and n fourth sublayers 204 stacked alternately and periodically, where n≥1. The chalcogenide semiconductor material of the third sublayer 203 and the chalcogenide semiconductor material of the fourth sublayer 204 have the same constituent elements, and the atomic percentages of various elements are different.

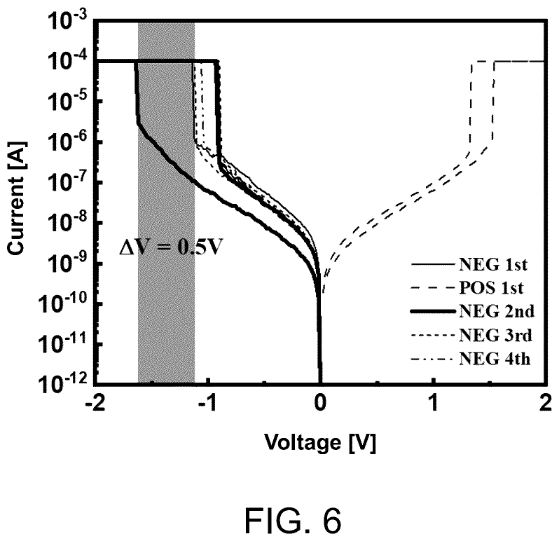

Specifically, the threshold switch layer includes a third sublayer 203 and a fourth sublayer 204 stacked alternately and periodically, the chalcogenide semiconductor material of the third sublayer 203 is GeTex and the chalcogenide semiconductor material of the fourth sublayer 204 is GeTey, and the atomic percentages of various elements are different, that is, x is not equal to y. In order to clearly show the change of the threshold state of the memory cell, in this embodiment, DC voltage scanning is adopted to focus on the analysis of the set operation and the read voltage range of the memory cell, and the results are shown in FIG. 6. In this embodiment, the negative electrical properties of the device are adopted to store information, and the negative direction of the voltage coordinates in FIG. 6 is specified as the positive operation of the non-volatile memory cell, that is, the electrical direction of the first scan operation is the positive direction of the voltage coordinate, and the electrical direction of the third scan operation is the negative direction of the voltage coordinate.

As shown in FIG. 6, the second scan operation (NEG 1 st in the figure) is performed on the device to obtain the initial threshold voltage of 1.1 V in the threshold switch layer, so that the device is in the initial threshold voltage state. In order to realize the reset (set “0”) operation, a reverse scan (POS 1st in the figure) is applied to the device, which is the reverse first scan operation applied.

Then, a third scan operation (NEG 2nd in the figure) is applied to the device, and the threshold voltage of the device reaches 1.62V, verifying that in this example, the increment ΔVth of the threshold voltage increases by 0.5V after the second scan operation (POS 1st in the figure), and the voltage threshold increases from the initial threshold voltage of 1.1 V to high threshold voltage of 1.62 V, and the range from 1.1 V to 1.62 V is the read voltage window of the memory cell. Compared with Example 1, a single threshold switch layer only achieves a threshold voltage increment of 0.35V, while the alternate stacking of threshold switch layer GeTex and threshold switch layer GeTey achieves a threshold voltage increment of 0.5V, further increased by 0.15V, confirming that the use of this asymmetric structure is helpful to realize the threshold voltage increment.

After undergoing NEG 3rd and NEG 4th voltage scans, the threshold voltage of the device is about 1.1V, indicating that after the third scan operation (NEG 2nd in the figure) turns on the device, the threshold voltage of the device spontaneously drops to 1.1V, that is, NEG 2nd realizes the set (set “1”) operation of the memory cell. In the meantime, the NEG 3rd and NEG 4th voltage scans show that the device will be stable in the “1” state after repeated conduction, confirming the non-volatility of the device when the device is repeatedly read.

The above are only preferred embodiments of the present disclosure, and are not intended to limit the present disclosure. Any modifications, equivalent replacements, improvements, etc. made within the spirit and principles of the present disclosure shall be included in the protection scope of the present disclosure.

What is claimed is:

1. A non-volatile memory cell based on a threshold switch, characterized in that the non-volatile memory cell comprises:
a first metal electrode layer, a threshold switch layer, and a second metal electrode layer stacked in sequence, wherein the threshold switch layer contains a chalcogenide semiconductor material, and a threshold voltage of the threshold switch layer is able to be switched between an initial threshold voltage and a high threshold voltage under an operation of an electric signal.

2. The non-volatile memory cell according to claim 1, characterized in that the threshold switch layer is a single-layer structure.

3. The non-volatile memory cell according to claim 1, characterized in that the threshold switch layer is an asymmetric multi-layer structure, and the threshold switch layer comprises m first sub-layers and m second sub-layers stacked alternately and periodically, wherein m≥1, and a chalcogenide semiconductor material of the first sublayer is different from a chalcogenide semiconductor material of the second sublayer.

4. The non-volatile memory cell according to claim 3, characterized in that constituent elements of the chalcogenide semiconductor material in the first sublayer and the chalcogenide semiconductor material in the second sublayer are different, or the constituent elements of the chalcogenide semiconductor material of the first sublayer and the chalcogenide semiconductor material of the second sublayer are the same, and atomic percentages of the elements are different.

5. The non-volatile memory cell according to any one of claims 1-4, characterized in that the chalcogenide semiconductor material is selected from at least one of SiTex, CTex, BTex, GeTex, AlTex, GeSbx, BiTex, AsTex, SnTex, MgTex, GeSex, SbSex, BiSex, AsSex, GeSx, and GaSx, or the chalcogenide semiconductor material is selected from at least one of doped SiTex, CTex, BTex, GeTex, AlTex, GeSbx, BiTex, AsTex, SnTex, MgTex, GeSex, SbSex, BiSex, AsSex, GeSx, and GaSx, and a doping element is selected from at least one of N, Sb, Si, and C.

6. An operation method of a non-volatile memory cell based on a threshold switch, adapted for the non-volatile memory cell according to any one of claims 1-5, characterized in that the operation method comprises a reset operation, and specifically comprises:
when the threshold voltage of the threshold switch layer is at the initial threshold voltage, performing a first scan operation on the non-volatile memory cell, so that the threshold voltage of the threshold switch layer is switched from the initial threshold voltage to the high threshold voltage, wherein a voltage amplitude of the first scan operation is higher than the initial threshold voltage, the first scan operation and a second scan operation have opposite electrical properties, and the second scan operation is an initial operation for obtaining the initial threshold voltage of the threshold switch layer.

7. The operation method of the non-volatile memory cell according to claim 6, characterized in that the operation method further comprises a set operation, and specifically comprises:
when the threshold voltage of the threshold switch layer is at the high threshold voltage, performing a third scan operation on the non-volatile memory cell, so that the threshold voltage of the threshold switch layer is switched from the high threshold voltage to the initial threshold voltage, an amplitude of the third scan operation is higher than the high threshold voltage, and the third scan operation has the same electrical properties as the second scan operation.

8. The operation method of the non-volatile memory cell according to claim 6, characterized in that the operation method further comprises a read operation, and specifically comprises:
performing a fourth scan operation on the non-volatile memory cell, wherein a voltage of the fourth scan operation is between the initial threshold voltage and the high threshold voltage.

9. The operation method of the non-volatile memory cell according to claim 6, characterized in that the first scan operation is DC scanning or pulse scanning, a waveform of the pulse scanning comprises a square wave, a triangular wave and a trapezoidal wave, an absolute value of a DC scanning range or an absolute value of a pulse scanning amplitude of the first scan operation is greater than the initial threshold voltage, and a pulse width of the pulse scanning is greater than a minimum value for turning on the non-volatile memory cell.

10. The operation method of the non-volatile memory cell according to claim 7, characterized in that the third scan operation is DC scanning or pulse scanning, and a waveform of the pulse scanning comprises a square wave, a triangular wave and a trapezoidal wave, an absolute value of a DC scanning range or an absolute value of a pulse scanning amplitude of the third scan operation is greater than the high threshold voltage, and a pulse width of the pulse scanning is greater than a minimum value for turning on the non-volatile memory cell.
